(19) United States
(12) Patent Application Publication
(10) Pub. No.: US 2025/0183164 A1
(43) Pub. Date: Jun. 5, 2025

(54) METHODS FOR FORMING THIN FILM RESISTOR

(71) Applicants: Chi-Han Yang, Hsinchu (TW); Chih-Yu Tseng, Hsinchu (TW); Kuo Liang Wang, Hsinchu (TW)

(72) Inventors: Chi-Han Yang, Hsinchu (TW); Chih-Yu Tseng, Hsinchu (TW); Kuo Liang Wang, Hsinchu (TW)

(21) Appl. No.: 18/529,008

(22) Filed: Dec. 5, 2023

(51) Int. Cl. H01L 23/522

(52) U.S. Cl. CPC H01L 23/5228; H10D 1/47

(57) ABSTRACT

A thin film resistor structure for a semiconductor package comprises a resistor sheet; and two landing pads at opposite ends of the resistor sheet with sidewall spacers around each landing pad. The thin film resistor structure can be made in a back-end-of-line (BEOL) process. The sidewall spacers increase process control by reducing undercutting of the landing pad that can occur during manufacture, and which can permit damage to the resistor sheet in subsequent processing steps.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Thin film resistors can be made as part of such integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view showing a first example embodiment of a resistor structure, in accordance with some embodiments. The resistor includes sidewall spacers around two landing pads of the resistor structure.

FIG. 1B is a cross-sectional view showing a second example embodiment of a resistor structure, in accordance with some embodiments. In this embodiment, peripheral portions of the sidewall spacers extend below the resistor sheet of the resistor structure.

FIG. 2A and FIG. 2B together are a flow chart illustrating a method for forming the resistor structure, in accordance with some embodiments. Various steps of this method are shown in FIGS. 3-17.

FIG. 3 is a cross-sectional view after forming an optional metal contact and then a first dielectric layer.

FIG. 4 is a cross-sectional view after planarizing the first dielectric layer to obtain a flat surface.

FIG. 5 is a cross-sectional view after forming a buffer layer upon the first dielectric layer.

FIG. 6 is a cross-sectional view after forming a resistor material layer, a barrier metal layer, and a hard mask layer upon the buffer layer.

FIG. 7 is a cross-sectional view after patterning to form a resistor stack.

FIG. 8 is a cross-sectional view after etching to expose a portion of the barrier metal layer.

FIG. 9 is a cross-sectional view after partial etching of the exposed portion of the barrier metal layer.

FIG. 10 is a cross-sectional view after applying a spacer film layer over the resistor stack.

FIG. 11A is a cross-sectional view after a processing step, when the sidewall spacers are formed by etching of the spacer film layer.

FIG. 11B is a plan view of the structure of FIG. 11A.

FIG. 11C is a cross-sectional view of a second embodiment. Here, the sidewall spacers extend below the resistor material layer or resistor sheet.

FIG. 12 is a cross-sectional view after completely etching away the exposed portion of the barrier metal layer to form the resistor structure.

FIG. 13 is a cross-sectional view after applying a capping layer over the resistor structure.

FIG. 14 is a cross-sectional view after forming a second dielectric layer.

FIG. 15 is a cross-sectional view after planarizing the second dielectric layer to obtain a flat surface.

FIG. 16 is a cross-sectional view after forming vias to the two landing pads of the resistor structure.

FIG. 17 is a cross-sectional view after filling the vias with an electrically conductive material.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them.

The term “semiconductor die”, or “chip”, or “microchip” are used interchangeably in the present disclosure to refer to the combination of a substrate and the multiple layers upon the substrate which form one or more integrated circuits.

The term “semiconductor package”, as used in the present disclosure, refers to the combination of a semiconductor die and an interconnect layer that permits the semiconductor die to communicate with one or more other packages. Examples of an interconnect layer may include a redistribution layer (RDL) or an interposer having bond pads or C4 bumps or pillars. Thus, a semiconductor package may have an interconnect layer on only one side, or on both sides, as will be seen further herein. It is noted that in the art, the term “package” is used to refer to many different structures and does not have a single fixed definition.

The present disclosure relates to various methods for improving the performance of a thin film resistor and corresponding resistor structures, especially in back-end-of-line (BEOL) processes. Thin film resistors (TFRs) are useful components in high precision analog and mixed signal applications, such as in a radio frequency (RF) circuit like an oscillator, phase-shift network, filter, or converter; memory like a dynamic random access memory (DRAM) or a static random access memory (SRAM) circuit; or other analog or mixed-signal circuits. TFRs may be part of an individual device, or may be part of a complex hybrid circuit or integrated circuit. The resistance of a TFR depends on the volume of the material used for the resistive portion of the resistor. In the present disclosure, sidewall spacers are added to the resistor structure. This reduces/prevents undercutting and provides greater ability to control the final resistance of the TFR.

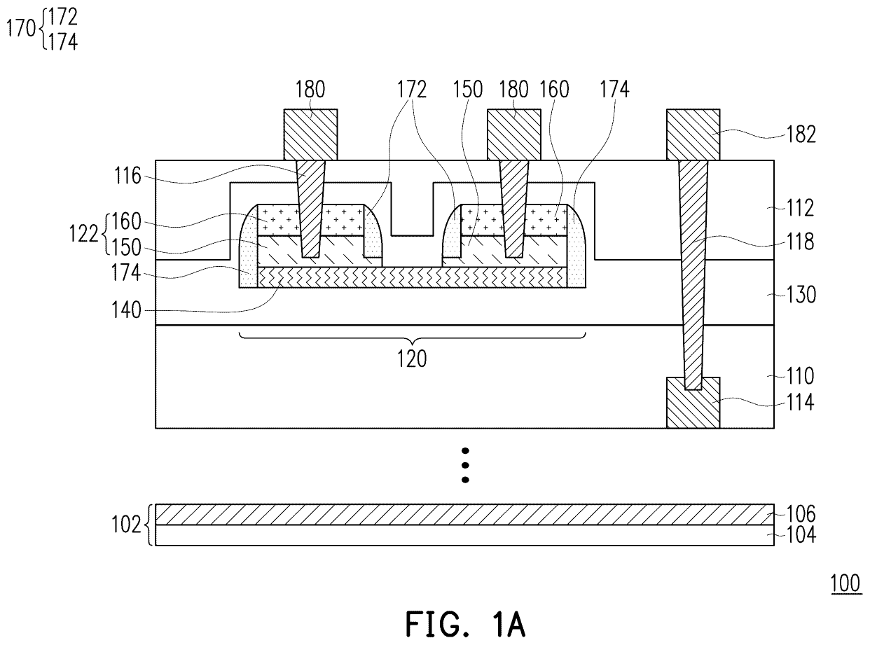

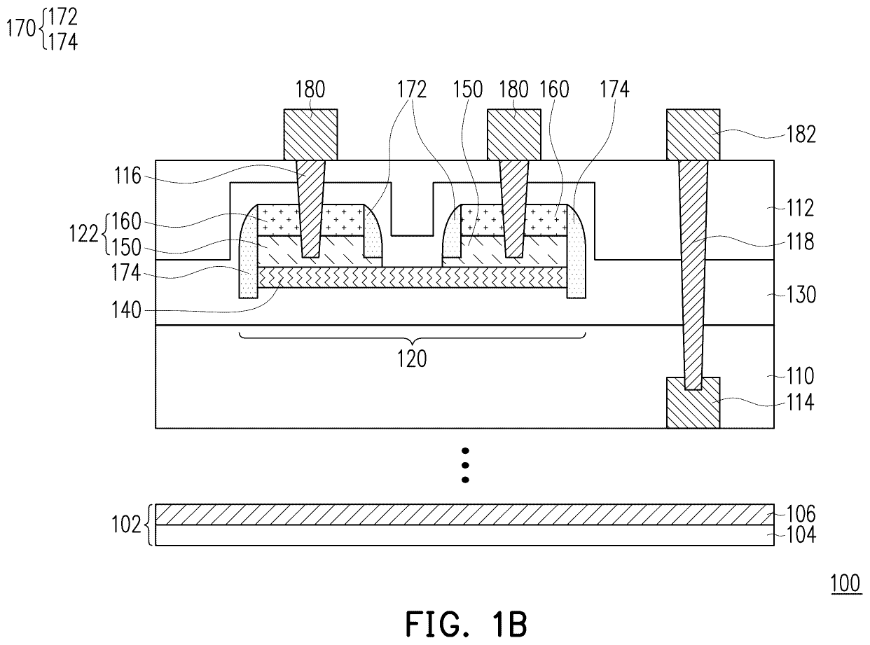

FIG. 1A is a cross-sectional view showing a first example embodiment of a resistor structure, in accordance with some embodiments. The resistor structure is part of an overall semiconductor package, and is discussed herein as being fabricated during the back-end-of-line (BEOL) process, after the integrated circuit(s) have been formed and when various semiconductor dies are interconnected to form desired electrical circuits. However, the various process steps described herein are also applicable to fabrication of the resistor structure during a front-end-of-line (FEOL) process.

Initially, the semiconductor package 100 includes a semiconductor die 102, upon which the resistor structure will be built. The die includes a substrate 104 and multiple layers upon the substrate which form an integrated circuit, shown here as one layer 106.

The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zirconium oxynitride (ZrOₓN_{y}), or silicon oxynitride (SiOₓN_{y}), where 0<x, y, ≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

Continuing, the resistor structure 120 is formed between a first dielectric layer 110 and a second dielectric layer 112. These two layers may independently be considered intermetal dielectric (IMD) layers or interlayer dielectric (ILD) layers. The first dielectric layer 110 may also be considered a pre-metal dielectric (PMD) layer. These two dielectric layers may be at any level of the interconnect layers upon the semiconductor die 102. A metal contact 114 is illustrated as being present within the first dielectric layer 110.

The resistor structure 120 itself includes a resistor sheet 140 and two landing pads 122. Each landing pad 122 includes a barrier metal layer 150 and a hard mask layer 160. A sidewall spacer 170 is present around each landing pad. Each sidewall spacer may be considered to have an interior portion 172 and a peripheral portion 174. The interior portion is located above the resistor sheet, and the peripheral portion is not located above the resistor sheet. The resistor structure is embedded within a buffer cap layer 130, which is also formed from a dielectric material.

A pair of vias 116 is shown extending through the second dielectric layer 112 and the buffer cap layer 130 to each of the landing pads 122. A through-via 118 is shown extending through the second dielectric layer 112, the buffer cap layer 130, and the first dielectric layer 110 to the metal contact 114. Finally, metal contacts 180, 182 are present upon the second dielectric layer 112. An electrical circuit can thus be formed that passes through the resistor structure 120. The through-via 118 permits current to flow to the first dielectric layer and any other components formed therein or in layers below the first dielectric layer while bypassing the resistor structure 120.

FIG. 1B is a cross-sectional view showing a second example embodiment of a resistor structure, in accordance with some embodiments. In this second embodiment, the peripheral portions 174 of the sidewall spacers 170 extend below the resistor sheet 140.

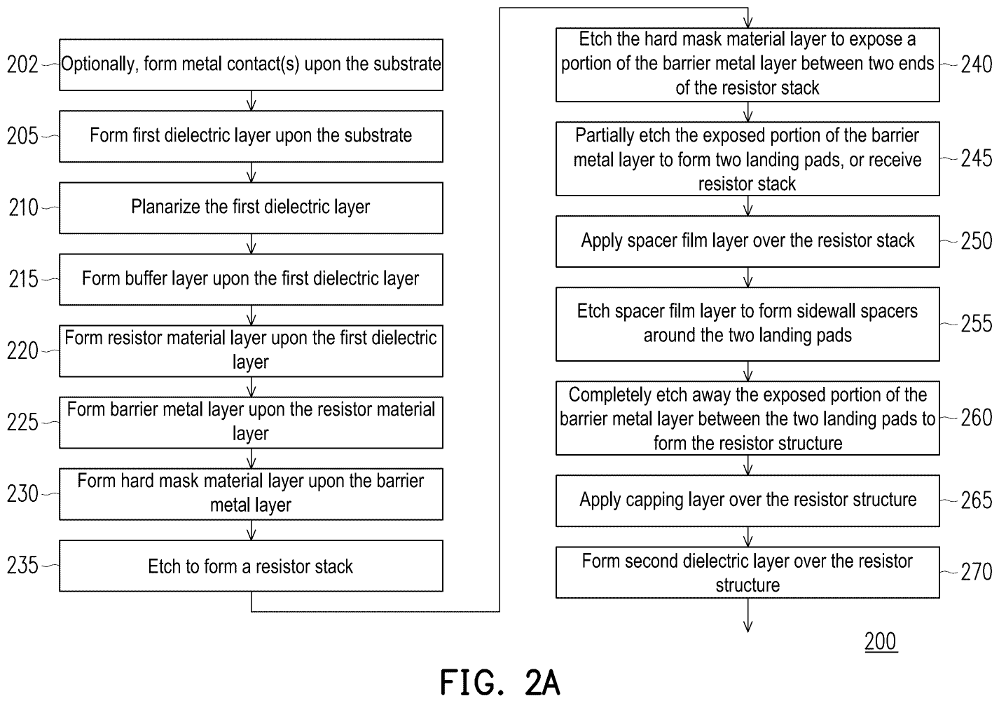

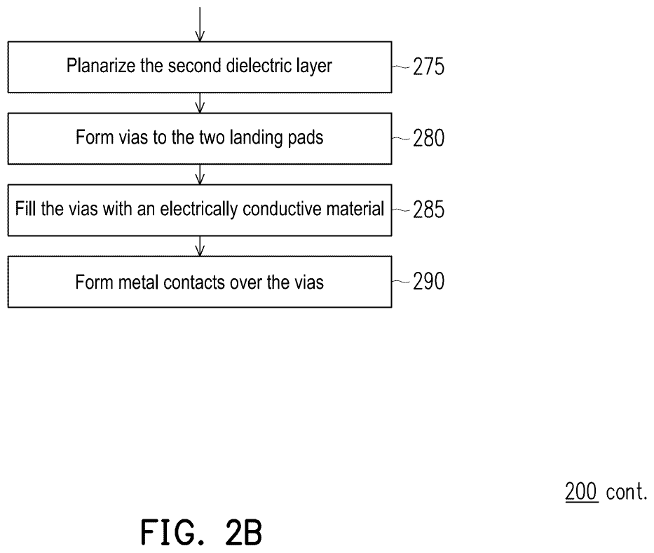

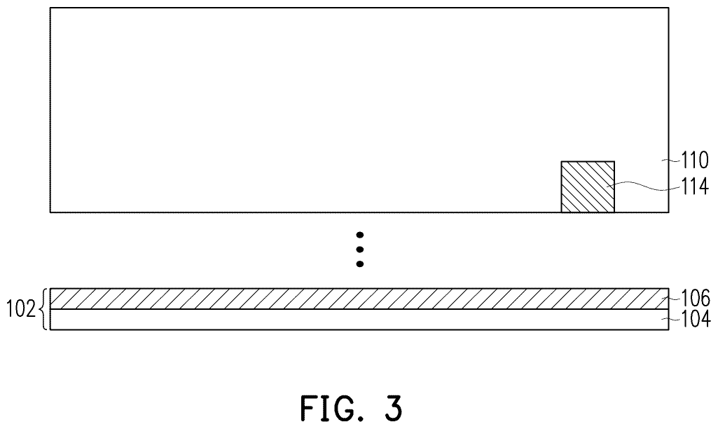

FIG. 2A and FIG. 2B together form a flow chart illustrating a method 200 for making a resistor structure in a back-end-of-line process, in accordance with some embodiments. Some steps of the method are also illustrated in FIGS. 3-17. These figures provide different views for better understanding. While the method steps are discussed below in terms of forming a single resistor in a BEOL process, such discussion should also be broadly construed as applying to the formation of multiple resistors concurrently and/or in an FEOL process.

It is noted that certain conventional steps are not expressly described in the discussion below. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Continuing, then, and referring to optional step 202 of FIG. 2A and as illustrated in FIG. 3, one or more metal contacts 114 are formed upon the substrate 104 or upon the semiconductor die 102. Then, in step 205, a first dielectric layer 110 is formed upon the substrate 104. The first dielectric layer also covers the metal contact 114. (The semiconductor die 102 is omitted in further figures for convenience.)

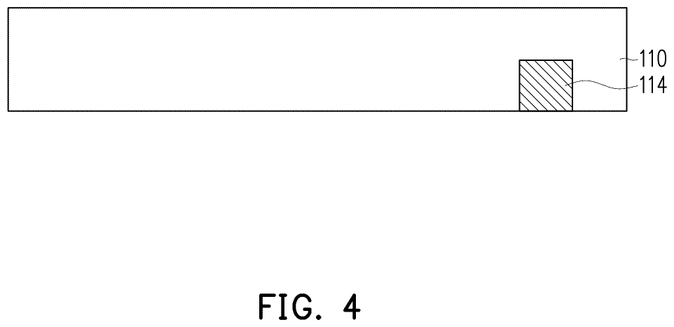

Next, in step 210 of FIG. 2A and as illustrated in FIG. 4, the first dielectric layer 110 is planarized to obtain a flat surface. The planarizing may be performed, for example, using a chemical mechanical polishing (CMP) process.

Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

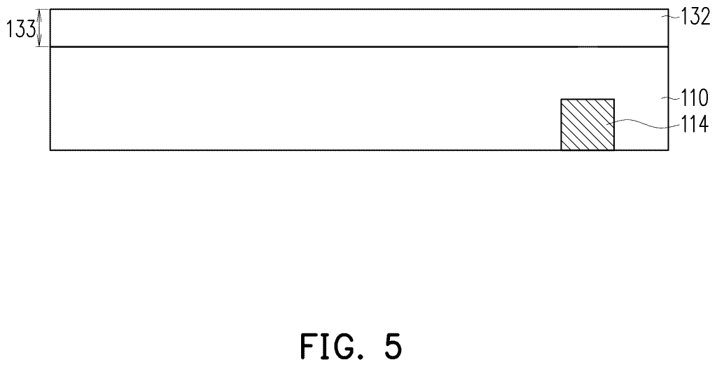

Next, in step 215 of FIG. 2A and as illustrated in FIG. 5, a buffer layer 132 is formed upon the first dielectric layer 110. This buffer layer may also be referred to as a first buffer cap oxide layer. The buffer layer is also formed from a dielectric material, and is typically formed from suitable oxides such as silicon dioxide (SiO₂), aluminum oxide (Al₂O₃), hafnium dioxide (HfO₂), or zirconium dioxide (ZrO₂). The buffer layer can be formed by physical vapor deposition (PVD) or chemical vapor deposition (CVD) or other suitable process. For example, a silicon-containing source gas may act as a silicon precursor that reacts with an oxygen-containing source gas. Examples of such silicon precursors include but are not limited to tetraethyl orthosilicate (TEOS), trimethylsilane, tetramethylsilane, and hexachlorodisilane (HCDS). Ozone (O₃) can be used to provide oxygen atoms for the reaction. At temperatures of about 300° C. to about 500° C. or higher, these gases will react to deposit silicon dioxide. The buffer layer 132 may have a thickness 133 of about 800 angstroms to about 1200 angstroms, and in some specific embodiments has a thickness of about 1000 angstroms, although other values and ranges are also within the scope of this disclosure.

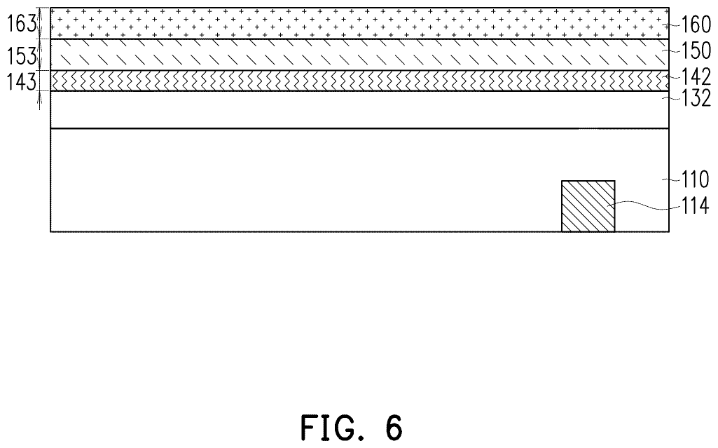

Referring now to FIG. 6, in step 220 of FIG. 2A, a resistor material layer 142 is formed upon the buffer layer 132. This layer will eventually be shaped into a resistive sheet that provides the electrical resistance of the resistor structure. The resistor material layer may be formed by PVD, CVD, sputtering, or other suitable process. The resistor material layer can be formed from suitable materials such as SiCr, NiCr, TaN, RuO₂, PbO, Bi₂Ru₂O₇, or Bi₂Ir₂O₇. In particular embodiments, the resistor material layer is formed from SiCr. The resistor material layer 142 may have a thickness 143 of about 30 angstroms to about 100 angstroms, and in some specific embodiments has a thickness of about 50 angstroms, although other values and ranges are also within the scope of this disclosure.

In step 225 of FIG. 2A, a barrier metal layer 150 is formed upon the resistor material layer 142. The barrier metal layer may be formed by PVD, CVD, sputtering, or other suitable process. The barrier metal can be any suitable material such as titanium nitride (TiN), indium oxide (In₂O₃), tantalum nitride (TaN), tungsten nitride, tungsten silicide, cobalt, ruthenium, or tantalum. It is noted that some of these materials are actually ceramics, but are considered “barrier metals” by one of ordinary skill in the art because they have the common functional property of chemically isolating two materials on opposite sides while still maintaining an electrical connection between the two materials. In particular embodiments, the barrier metal layer is formed from TiN. The barrier metal layer 150 may have a thickness 153 of about 600 angstroms to about 900 angstroms, and in some specific embodiments has a thickness of about 750 angstroms, although other values and ranges are also within the scope of this disclosure.

Then, in step 230 of FIG. 2A, a hard mask layer 160 is formed upon the barrier metal layer 150. Again, the hard mask layer may be formed by PVD, CVD, sputtering, or other suitable process. The hard mask material can be any suitable material, and in particular embodiments is silicon oxynitride (SiOₓN_{y}), The hard mask layer 160 may have a thickness 163 of about 200 angstroms to about 500 angstroms, and in some specific embodiments has a thickness of about 320 angstroms, although other values and ranges are also within the scope of this disclosure. The resulting structure after step 230 is shown in FIG. 6.

In some particular embodiments, the barrier metal layer thickness 153 and the hard mask layer thickness 163 together have a total thickness of about 1000 angstroms to about 1200 angstroms, although other values and ranges are also within the scope of this disclosure.

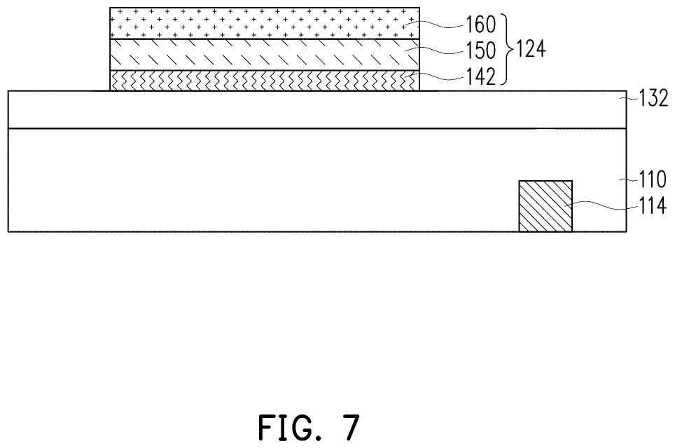

A photoresist layer is applied and patterned using a first mask (MO). In step 235 of FIG. 2A, etching is performed to form a resistor stack 124 from the resistor material layer 142, the barrier metal layer 150, and the hard mask layer 160. The photoresist layer is then removed. The resulting structure is shown in FIG. 7. It is noted the resistor material can now be considered a resistor sheet 140. The thickness of the resistor sheet is the same as that of the resistor material layer.

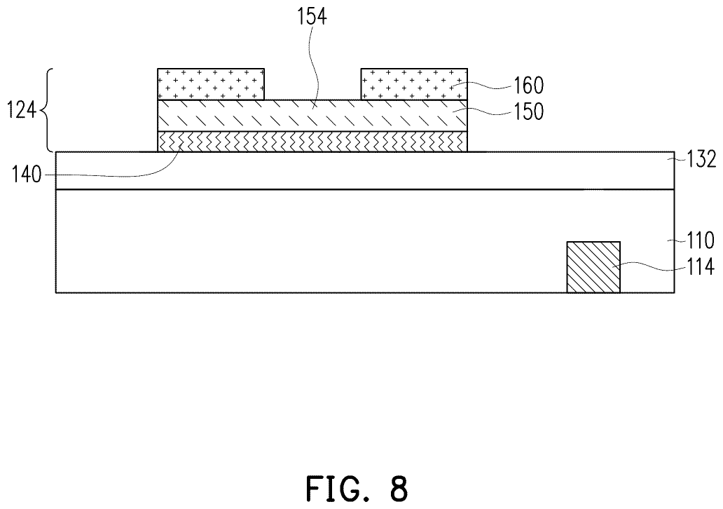

Another photoresist layer is applied and patterned using a second mask (MR). In step 240 of FIG. 2A, the hard mask layer 160 is then etched to expose a portion 154 of the barrier metal layer between two ends of the resistor stack; The photoresist layer is then removed. The resulting structure is shown in FIG. 8.

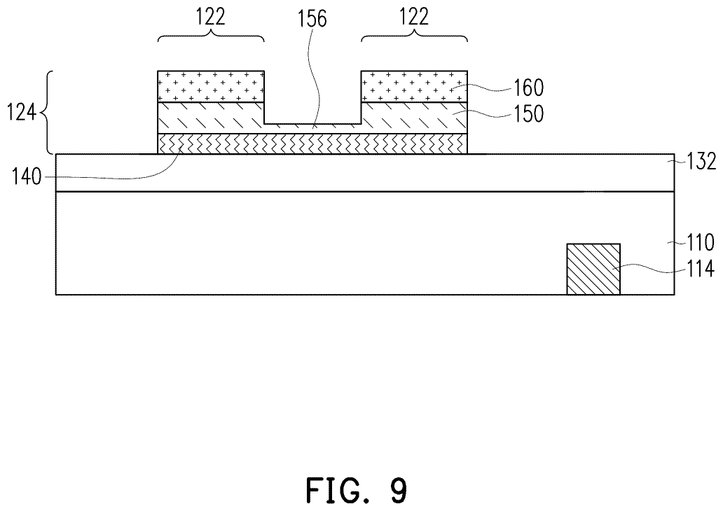

Next, in step 245 of FIG. 2A, the exposed portion 154 of the barrier metal layer is partially etched. In particular embodiments, the partial etching is performed using dry etching. The resulting structure is shown in FIG. 9. As seen here, this partial etching forms two landing pads 122 at the ends of the resistor stack, or at opposite ends or sides of the resistor sheet 140. Each landing pad 122 includes a barrier metal layer 150 and a hard mask layer 160. It should be noted that a thin layer 156 of the barrier metal layer is still present over the resistor sheet, and the resistor sheet is not yet exposed from the top. In broader embodiments of the method 200, a resistor stack 124 having the structure thus described is received.

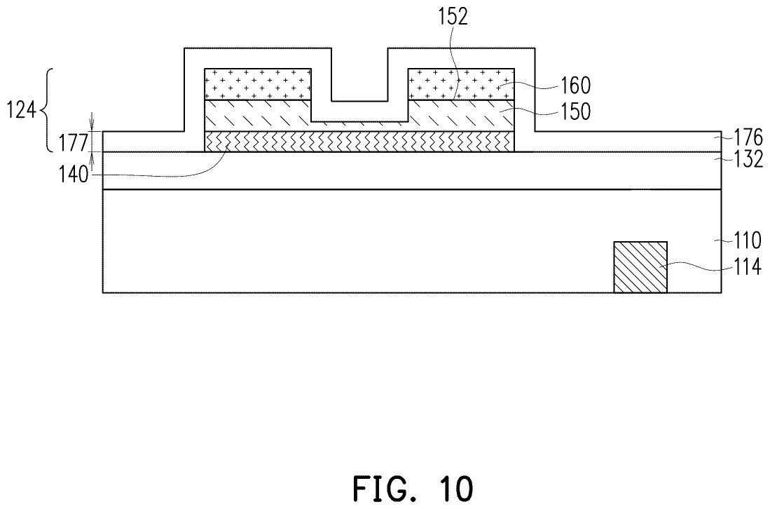

Next, in step 250 of FIG. 2A, a spacer film layer 176 is applied over the resistor stack, or in other words over the substrate (not shown). The resulting structure is shown in FIG. 10. The spacer film layer is formed from a dielectric material, and is different from the hard mask material and the barrier metal. The spacer film layer may be formed by CVD, or atomic layer deposition (ALD), or other suitable process. The spacer film layer 176 may have a thickness 177 of about 20 angstroms to about 100 angstroms, although other values and ranges are also within the scope of this disclosure. The spacer film layer may be described generally as adhering to the exposed surfaces of the various layers underneath it. It should also be noted that the spacer film layer extends below the upper surface 152 of the barrier metal layer 150.

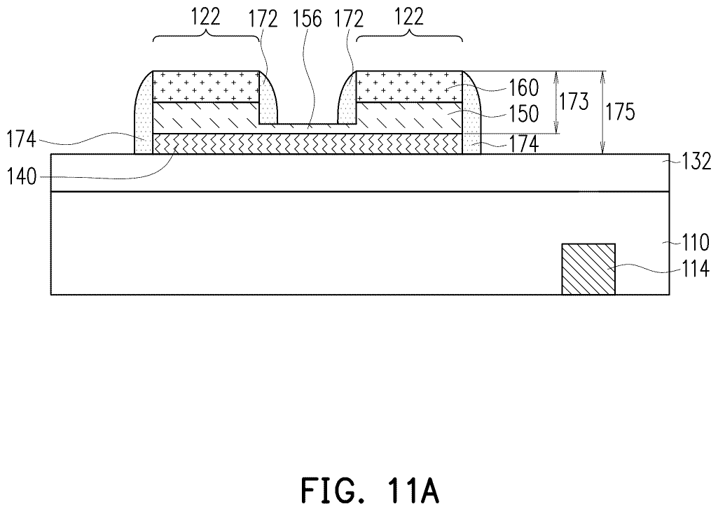

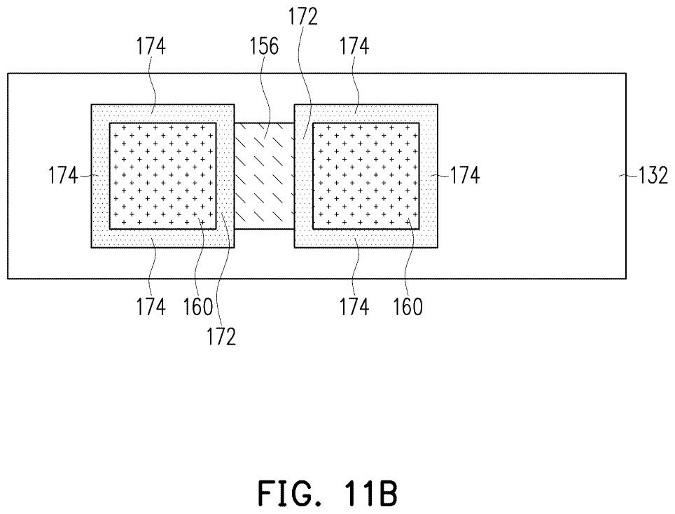

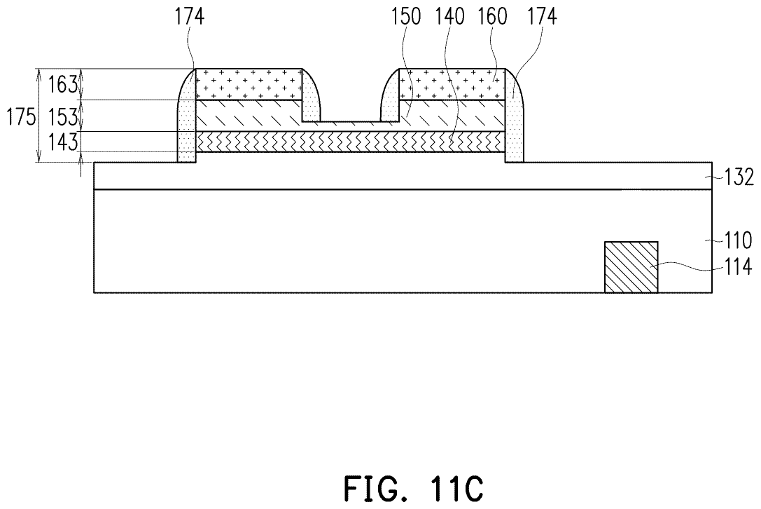

Then, in step 255 of FIG. 2A, the spacer film layer is etched to form sidewall spacers 170 around the two landing pads 122. The etching process removes the horizontal portions of the spacer film layer, leaving behind the vertical portions. A cross-sectional view of the resulting structure is shown in FIG. 11A, and a plan view is provided in FIG. 11B. It is noted that the thin layer 156 of the barrier metal layer 150 protects the resistor sheet 140 from being damaged during this etching step.

Referring first to FIG. 11A, the interior portion 172 of the sidewall spacer 170 is located above the resistor sheet 140 and contacts the upper surface of the barrier metal layer 150. However, the interior portion 172 of the sidewall spacer does not contact the buffer layer 132. The peripheral portion 174 of the sidewall spacer 170 contacts the sides of the resistor sheet 140 and the barrier metal layer 150. The peripheral portion 174 of the sidewall spacer 170 also contacts the upper surface of the buffer layer 132. In some specific embodiments, the thickness 175 of the peripheral portion of the sidewall spacer 174 may be equal to or greater than the thickness 173 of the interior portion of the sidewall spacer 172. In some embodiments, the thickness 173, 175 of the portions of the sidewall spacer may independently be from about 800 angstroms to about 1500 angstroms, although other values and ranges are also within the scope of this disclosure.

Referring now to the plan view of FIG. 11B, the sidewall spacer 170 is illustrated here as having the shape of a four-sided square. Speaking more generally, the sidewall spacer may have any desired shape as desired, for example a circular, triangular, rectangular, or other polygonal shape. As illustrated here, the interior portion 172 of the sidewall spacer makes up one side of the square, and the peripheral portion 174 of the sidewall spacer makes up the other three sides of the square. The exposed portion 154 of the barrier metal layer is visible between the two interior portions 172 of the sidewall spacers. The hard mask layer 160 of each landing pad is also visible.

It is noted that during step 245 in which the exposed portion 154 of the barrier metal layer is partially etched, the exposed buffer layer 132 may also be partially etched. As a result, the thickness of the exposed buffer layer may be decreased. Thus, in some embodiments, when the spacer film layer 176 is deposited and then etched to form the sidewall spacers 170, the peripheral portions 174 of the sidewall spacers may extend below the resistor material layer 142/resistor sheet 140. This structure is illustrated in FIG. 11C. In this embodiment, the thickness 175 of the peripheral portion of the sidewall spacer is greater than the sum of the resistor sheet thickness 143, the barrier metal layer thickness 153, and the hard mask layer thickness 163.

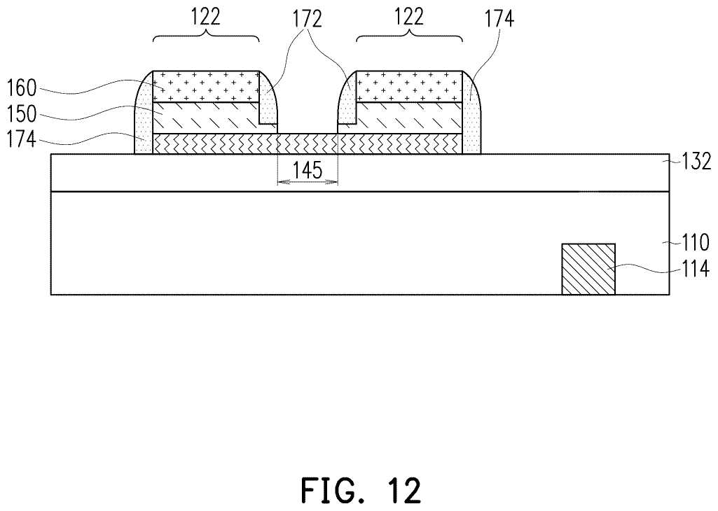

Next, in step 260 of FIG. 2A, the exposed portion of the barrier metal layer between the two landing pads is completely etched away to form the resistor structure. The resulting structure is shown in FIG. 12. In particular embodiments, this step is performed by wet etching, which may provide better selectivity for the barrier metal than the resistor sheet, so that the resistor sheet is not damaged. As illustrated here, the presence of the sidewall spacers 170 reduces or prevents undercutting of the barrier metal layer which might otherwise occur, especially on the peripheral portions of the barrier metal layer. If any undercutting does occur, it occurs under the interior portion 172 of the sidewall spacer, which is much less than is otherwise exposed underneath the hard mask layer 160. The resistor length 145 is the distance between the two landing pads 122. In some specific embodiments, the resistor length is from about 1 micrometer to about 100 micrometers, although other values and ranges are also within the scope of this disclosure.

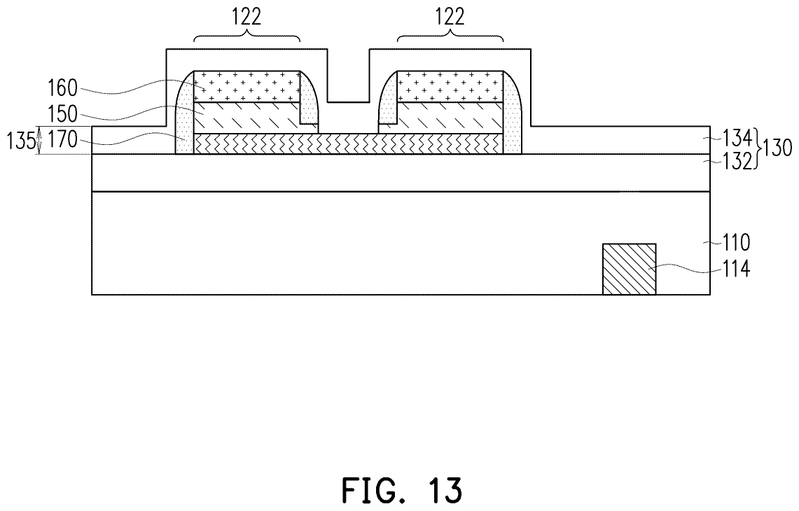

Next, in step 265 of FIG. 2A and as illustrated in FIG. 13, a capping layer 134 is applied over the resistor structure. The capping layer 134 may also be applied over the exposed buffer layer 132. The capping layer is formed from a dielectric material. The capping layer may be formed by PVD, CVD, ALD, or other suitable process. In particular embodiments, the dielectric material of the capping layer 134 is the same material as used for the buffer layer 132, and these two layers together form the buffer cap layer 130 of FIG. 1. The dielectric material of the capping layer 134 is usually different from the material used to form the hard mask layer 160, the barrier metal layer 150, and the sidewall spacers 170. The capping layer 134 may have a thickness 135 of about 300 angstroms to about 700 angstroms, and in some specific embodiments has a thickness of about 500 angstroms, although other values and ranges are also within the scope of this disclosure.

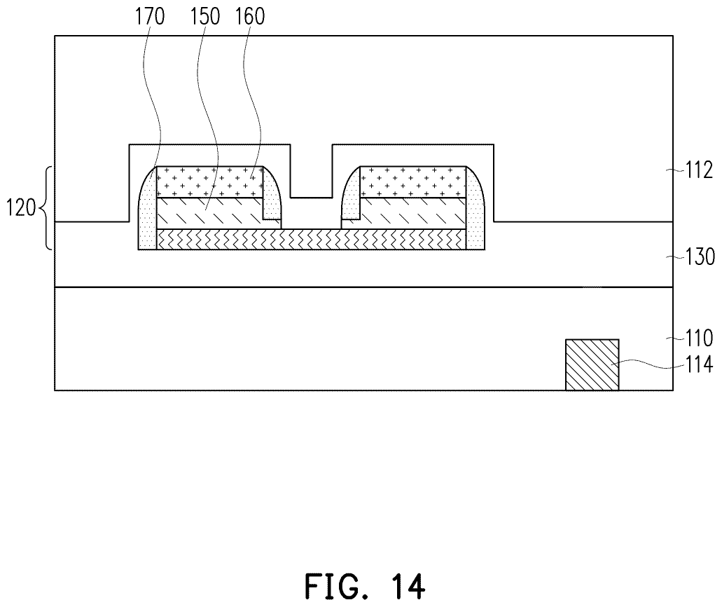

Then, in step 270 of FIG. 2A, a second dielectric layer 112 is formed upon the substrate and over the resistor structure 120. The resulting structure is shown in FIG. 14.

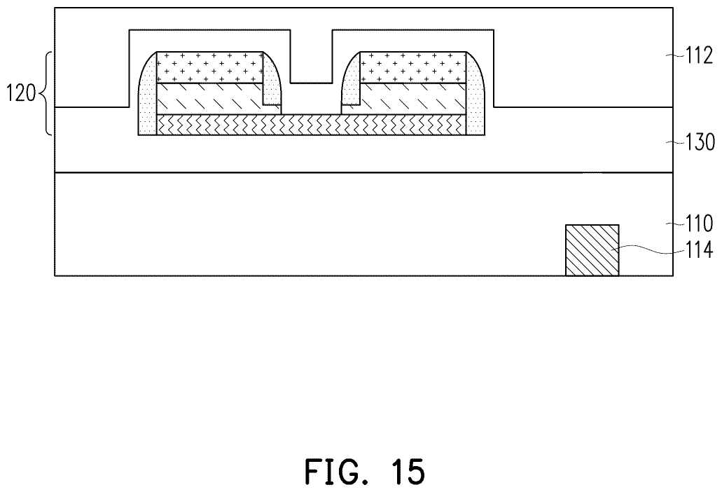

Next, in step 275 of FIG. 2B and as illustrated in FIG. 15, the second dielectric layer 112 is planarized to obtain a flat surface. Again, the planarizing may be performed, for example, using a CMP process.

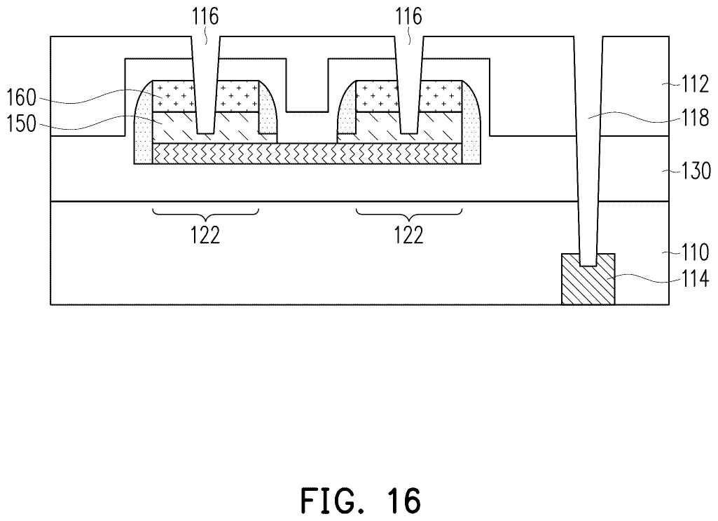

In step 280 of FIG. 2B and as illustrated in FIG. 16, vias 116 are formed to the two landing pads 122. More specifically, the vias pass through the hard mask layer 160 and terminate in the barrier metal layer 150. This may be done by etching, or could also be done by laser drilling. As also illustrated in FIG. 16, in this step, a through-via 118 can also be made to the metal contact 114 in the first dielectric layer 110.

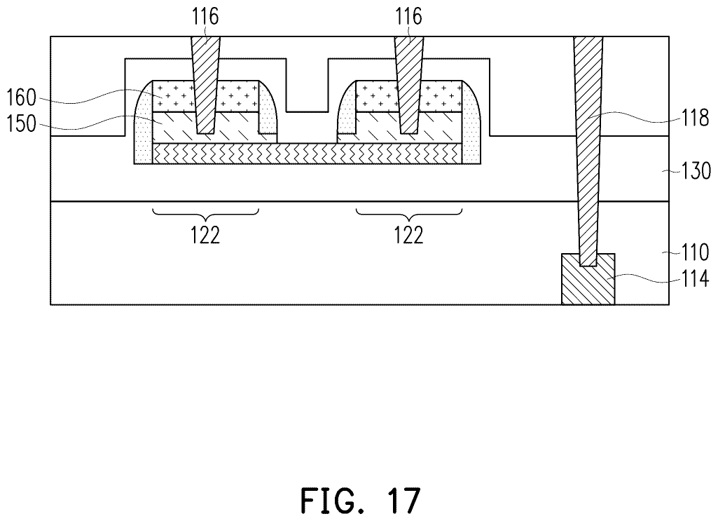

Next, in step 285 of FIG. 2B and as illustrated in FIG. 17, the vias 116 are filled with an electrically conductive material. The through-via 118 is also filled.

Then, in step 290 of FIG. 2B and as illustrated in FIG. 1, metal contacts 180 are formed over the vias 116. These metal contacts can also be described as being located over the landing pads 122 of the resistor structure, or over the second dielectric layer 112. A metal contact 182 is also formed over the through-via 118.

The methods and systems of the present disclosure are advantageous. Referring back to FIG. 2A and FIG. 8, if the sidewall spacers were not formed in steps 245-255, then etching of the barrier metal layer 150 would be performed next in step 260. In the absence of the sidewall spacers, all of the exposed surfaces of the barrier metal layer 150 would be etched, and it is difficult to prevent undercutting below the hard mask layer 160. This results in the formation of voids 190 in the barrier metal layer. Then, during deposition of the capping layer as shown in FIG. 13, the deposited material most readily adheres to the exposed surfaces of the various layers. The presence of the voids would result in little or no material being present to build up the capping layer on the vertical sides of the barrier metal layer, which results in the voids also extending through the capping layer 134, particularly along the perimeter of the resistor sheet 140. Finally, as mentioned above, after CMP, a post-CMP cleaning step is then carried out, for example using a fluid such as dilute hydrofluoric acid (DHF). Referring now to FIG. 15, it should be remembered that these figures are illustrative drawings of structures with layers having thicknesses measured in angstroms. The second dielectric layer 112 may include seams that connect to the voids which can be formed when sidewall spacers are not present. When this occurs, the DHF used in the post-CMP cleaning step can penetrate through a seam into a void, which can result in damage to the resistor sheet 140. The use of sidewall spacers 170 as in the present disclosure reduces or prevents undercutting of the barrier metal layer, which can affect control of the resistance present in the resistor structure due to damage of the resistor sheet 140. This improves process control and results in higher device quality, reproducibility, and overall device yield.

Additional processing steps may be performed to obtain devices with semiconductor packages containing the resistor structure. Those semiconductor packages might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

Some aspects of the present disclosure thus relate to methods for forming a resistor structure. A resistor stack is received which comprises a resistor sheet, two landing pads at opposite ends of the resistor sheet, and an exposed portion of a barrier metal layer between the two landing pads. A spacer film layer is applied over the resistor stack, and then etched to form sidewall spacers around the two landing pads. The exposed portion of the barrier metal layer between the two landing pads is then etched away to form the resistor structure.

Also disclosed herein in various embodiments are methods for forming a resistor structure in a back-end-of-line process. A first dielectric layer is formed upon a substrate. A buffer layer is formed upon the first dielectric layer. A resistor material layer is formed upon the buffer layer. A barrier metal layer is formed upon the resistor material layer. A hard mask layer is formed upon the barrier metal layer. Etching is performed to form a resistor stack from the resistor material layer, the barrier metal layer, and the hard mask layer. Then, the hard mask layer is etched to expose a portion of the barrier metal layer between two ends of the resistor stack. The exposed portion of the barrier metal layer is then partially etched to form two landing pads at the ends of the resistor stack. A spacer film layer is applied over the resistor stack. The spacer film layer is then etched to form sidewall spacers around the two landing pads. Afterwards, the exposed portion of the barrier metal layer between the two landing pads is completely etched away to form the resistor structure. A capping layer is applied over the resistor structure. A second dielectric layer is then formed upon the substrate and over the resistor structure. Vias to the two landing pads are formed by etching. The vias are filled with an electrically conductive material. Metal contacts are then formed over the vias.

Also disclosed herein in various embodiments are resistor structures. The resistor structure comprises a resistor sheet; and two landing pads at opposite ends of the resistor sheet with sidewall spacers around each landing pad.

Also disclosed herein are semiconductor packages that contain the resistor structure. Such packages usually also include an integrated circuit (IC). Devices including such semiconductor packages are also contemplated, such as display panel drivers, image sensors, mobile telephones, facial recognition systems, motion sensors, power management devices, and/or image signal processors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a resistor structure, comprising:
receiving a resistor stack comprising a resistor sheet, two landing pads at opposite ends of the resistor sheet, and an exposed portion of a barrier metal layer between the two landing pads;
applying a spacer film layer over the resistor stack;
etching the spacer film layer to form sidewall spacers around the two landing pads; and
etching away the exposed portion of the barrier metal layer between the two landing pads to form the resistor structure.

2. The method of claim 1, wherein the resistor sheet comprises SiCr, NiCr, TaN, RuO₂, PbO, Bi₂Ru₂O₇, or Bi₂Ir₂O₇.

3. The method of claim 1, wherein the barrier metal layer comprises titanium nitride (TiN), indium oxide (In₂O₃), tantalum nitride (TaN), tungsten nitride, tungsten silicide, cobalt, ruthenium, or tantalum.

4. The method of claim 1, wherein the spacer film layer comprises a dielectric material.

5. The method of claim 1, wherein peripheral portions of the sidewall spacers extend below the resistor sheet.

6. The method of claim 1, wherein a length of the resistor sheet between the two landing pads is from about 1 micrometer to about 100 micrometers.

7. The method of claim 1, wherein the resistor sheet has a thickness of about 30 angstroms to about 100 angstroms.

8. The method of claim 1, wherein the landing pads each have a thickness of about 1000 angstroms to about 1200 angstroms.

9. The method of claim 1, wherein the two landing pads each comprise a barrier metal layer and a hard mask layer.

10. The method of claim 1, further comprising:
applying a capping layer over the resistor structure;
forming a second dielectric layer over the resistor structure;
etching to form vias to the two landing pads;
filling the vias with an electrically conductive material; and
forming metal contacts over the vias.

11. The method of claim 1, wherein the resistor stack is formed by:
forming a resistor material layer;
forming a barrier metal layer upon the resistor material layer;
forming a hard mask layer upon the barrier metal layer;
etching the resistor material layer, the barrier metal layer, and the hard mask layer to form a resistor stack; and
etching the hard mask layer to expose a portion of the barrier metal layer between two ends of the resistor stack; and
partially etching the exposed portion of the barrier metal layer to form the two landing pads at the ends of the resistor stack.

12. The method of claim 11, wherein the hard mask layer comprises silicon oxynitride (SiON).

13. The method of claim 11, wherein the resistor material layer is formed upon a buffer layer over a semiconductor die.

14. The method of claim 13, wherein the buffer layer is formed upon a first dielectric layer.

15. A resistor structure, comprising:
a resistor sheet; and
two landing pads at opposite ends of the resistor sheet with sidewall spacers around each landing pad.

16. The resistor structure of claim 15, wherein peripheral portions of the sidewall spacers extend below the resistor sheet.

17. The resistor structure of claim 15, wherein each landing pad comprises a barrier metal layer and a hard mask layer.

18. The resistor structure of claim 15, further comprising a buffer layer below the resistor sheet and a capping layer covering the resistor sheet and the two landing pads.

19. A method for forming a resistor structure in a back-end-of-line process, comprising:
forming a first dielectric layer upon a substrate;
forming a buffer layer upon the first dielectric layer;
forming a resistor material layer upon the buffer layer;
forming a barrier metal layer upon the resistor material layer;
forming a hard mask layer upon the barrier metal layer;
etching to form a resistor stack from the resistor material layer, the barrier metal layer, and the hard mask layer;
etching the hard mask layer to expose a portion of the barrier metal layer between two ends of the resistor stack;
partially etching the exposed portion of the barrier metal layer to form two landing pads at the ends of the resistor stack;
applying a spacer film layer over the resistor stack;
etching the spacer film layer to form sidewall spacers around the two landing pads;
completely etching away the exposed portion of the barrier metal layer between the two landing pads to form the resistor structure;
applying a capping layer over the resistor structure;
forming a second dielectric layer upon the substrate and over the resistor structure;
etching to form vias to the two landing pads;
filling the vias with an electrically conductive material; and
forming metal contacts over the vias.

20. The method of claim 19, wherein peripheral portions of the sidewall spacers extend below the resistor material layer.
